(19) United States
(12) Patent Application Publication
(10) Pub. No.: US 2018/0171466 A1
(43) Pub. Date: Jun. 21, 2018

(54) CARRIER FOR SUPPORTING AT LEAST ONE SUBSTRATE DURING A SPUTTER DEPOSITION PROCESS, APPARATUS FOR SPUTTER DEPOSITION ON AT LEAST ONE SUBSTRATE, AND METHOD FOR SPUTTER DEPOSITION ON AT LEAST ONE SUBSTRATE

(71) Applicants: Stefan KELLER, Mainaschaff (DE); Andre BRÜNING, Stockstadt (DE); Uwe SCHÜßLER, Aschaffenburg (DE); Thomas Werner ZILBAUER, Gauting (DE); Stefan BANGERT, Steinau (DE); Applied Materials, Inc., Santa Clara, CA (US)

(72) Inventors: Stefan KELLER, Mainaschaff (DE); Andre BRÜNING, Stockstadt (DE); Uwe SCHÜßLER, Aschaffenburg (DE); Thomas Werner ZILBAUER, Gauting (DE); Stefan BANGERT, Steinau (DE)

(73) Assignee: Applied Materials, Inc., Santa Clara, CA (US)

(21) Appl. No.: 15/737,442

(22) PCT Filed: Jul. 6, 2015
(86) PCT No.: PCT/EP2015/065366

§ 371 Date: Dec. 18, 2017

(51) Int. Cl. C23C 14/50; C23C 14/34; H01J 37/32; H01J 37/34; H01M 10/052

(52) U.S. Cl. CPC C23C 14/50; C23C 14/34; H01M 10/052; H01J 37/34; H01J 37/32715

(57) ABSTRACT

A carrier for supporting at least one substrate during a sputter deposition process is provided. The carrier includes a carrier body and an insulating portion provided at the carrier body. The insulating portion provides a surface of an electrically insulating material, wherein the surface is configured to face one or more sputter deposition sources during the sputter deposition process.

### TECHNICAL FIELD

Embodiments described herein relate to a carrier for supporting at least one substrate during a sputter deposition process, an apparatus for sputter deposition on at least one substrate, and a method for sputter deposition on at least one substrate. Embodiments described herein particularly relate to a passivated carrier for supporting at least one substrate during an AC sputter deposition process.

### BACKGROUND

Techniques for layer deposition on a substrate include, for example, thermal evaporation, chemical vapor deposition (CVD) and sputtering deposition. A sputter deposition process can be used to deposit a material layer on the substrate, such as a layer of an insulating material. During the sputter deposition process, a target having a target material to be deposited on the substrate is bombarded with ions generated in a plasma region to dislodge atoms of the target material from a surface of the target. The dislodged atoms can form the material layer on the substrate. In a reactive sputter deposition process, the dislodged atoms can react with a gas in the plasma region, for example, nitrogen or oxygen, to form an oxide, a nitride or an oxinitride of the target material on the substrate.

Coated substrates can be used, for example, in semiconductor devices and thin film batteries. Thin film batteries, such as lithium-ion batteries, are used in a growing number of applications, such as cell phones, notebooks and implantable medical devices. Thin film batteries provide beneficial characteristics with respect to, for example, form factors, cycle life, power capability and safety.

Carriers can be used for supporting a substrate during a deposition process, such as a sputter deposition process used in the manufacture of thin film batteries. During the sputter deposition process, arcing can occur due to potential differences within a vacuum processing chamber. Arcing can damage, for example, the carrier and/or the substrate. Further, arcing can affect homogeneity and/or purity of the material layer deposited on the substrate.

In light of the foregoing, there is a need to provide carriers for supporting at least one substrate during a sputter deposition process that overcome at least some of the problems in the art. The present disclosure particularly aims at providing a carrier, an apparatus and a method that can reduce or even avoid the occurrence of arcing in a vacuum processing chamber. The present disclosure further aims at a carrier, an apparatus and a method that allow for an improved homogeneity and purity of the material layer deposited on the at least one substrate.

### SUMMARY

In light of the above, a carrier for supporting at least one substrate during a sputter deposition process, an apparatus for sputter deposition on at least one substrate, and a method for sputter deposition on at least one substrate are provided. Further aspects, advantages, and features of the embodiments of the present disclosure are apparent from the dependent claims, the description and the accompanying drawings.

According to an aspect of the present disclosure, a carrier for supporting at least one substrate during a sputter deposition process is provided. The carrier includes a carrier body and an insulating portion provided at the carrier body, wherein the insulating portion provides a surface of an electrically insulating material, and wherein the surface is configured to face one or more sputter deposition sources during the sputter deposition process.

According to another aspect of the present disclosure, a carrier for supporting at least one substrate during a sputter deposition process is provided. The carrier includes a carrier body having two or more segments, wherein the two or more segments are configured for supporting the at least one substrate, and wherein the two or more segments are electrically insulated from each other.

According to yet another aspect of the present disclosure, an apparatus for sputter deposition on at least one substrate is provided. The apparatus includes a vacuum chamber, one or more sputter deposition sources in the vacuum chamber and a carrier for supporting the at least one substrate during a sputter deposition process. The carrier includes a carrier body and an insulating portion provided at the carrier body, wherein the insulating portion provides a surface of an electrically insulating material, and wherein the surface is configured to face the one or more sputter deposition sources during the sputter deposition process.

According to another aspect of the present disclosure, an apparatus for sputter deposition on at least one substrate is provided. The apparatus includes a vacuum chamber, one or more sputter deposition sources in the vacuum chamber and a carrier for supporting the at least one substrate during a sputter deposition process. The carrier includes a carrier body having two or more segments, wherein the two or more segments are configured for supporting the at least one substrate, and wherein the two or more segments are electrically insulated from each other.

According to an aspect of the present disclosure, a method for sputter deposition on at least one substrate is provided. The method includes positioning the at least one substrate on a carrier and depositing a layer of a material on the at least one substrate using an AC sputter deposition process. The carrier includes a carrier body and an insulating portion provided at the carrier body, wherein the insulating portion provides a surface of an electrically insulating material, and wherein the surface is configured to face one or more sputter deposition sources during the sputter deposition process.

According to another aspect of the present disclosure, a method for sputter deposition on at least one substrate is provided. The method includes positioning the at least one substrate on a carrier and depositing a layer of a material on the at least one substrate using an AC sputter deposition process. The carrier includes a carrier body having two or more segments, wherein the two or more segments are configured for supporting the at least one substrate, and wherein the two or more segments are electrically insulated from each other.

Embodiments are also directed at apparatuses for carrying out the disclosed methods and include apparatus parts for performing each described method aspect. These method aspects can be performed by way of hardware components, a computer programmed by appropriate software, by any combination of the two or in any other manner. Furthermore, embodiments according to the disclosure are also directed at methods for operating the described apparatus. The methods for operating the described apparatus include method aspects for carrying out every function of the apparatus.

### BRIEF DESCRIPTION OF THE DRAWINGS

So that the manner in which the above recited features of embodiments of the disclosure can be understood in detail, a more particular description of the embodiments, briefly summarized above, can be had by reference to embodiments described herein. The accompanying drawings relate to embodiments of the present disclosure and are described in the following:

FIG. 1 shows a front view of a carrier for supporting at least one substrate during a sputter deposition process according to embodiments described herein;

FIG. 2 shows a cross-sectional side view of the carrier of FIG. 1;

FIGS. 3A-C show cross-sectional side views of carriers having a coating according to embodiments described herein;

FIG. 4 shows a front view of a carrier for supporting at least one substrate during a sputter deposition process according to further embodiments described herein;

FIG. 5A shows a front view of a carrier for supporting at least one substrate during a sputter deposition process according to yet further embodiments described herein;

FIG. 5B shows a cross-sectional side view of the carrier of FIG. 5A;

FIG. 6A shows a front view of a carrier having two segments according to embodiments described herein;

FIG. 6B shows a front view of a carrier having two segments according to further embodiments described herein;

FIG. 7 shows a front view of a carrier having two segments according to yet further embodiments described herein;

FIG. 8 shows a schematic view of an apparatus for sputter deposition utilizing a carrier according to embodiments described herein; and

FIG. 9 shows a flow chart illustrating a method for sputter deposition according to embodiments described herein.

### DETAILED DESCRIPTION OF EMBODIMENTS

Reference will now be made in detail to the various embodiments of the present disclosure, one or more examples of which are illustrated in the figures. Within the following description of the drawings, the same reference numbers refer to the same components. Generally, only the differences with respect to individual embodiments are described. Each example is provided by way of explanation of embodiments of the disclosure and is not meant as a limitation of the embodiments. Further, features illustrated or described as part of one embodiment can be used on or in conjunction with other embodiments to yield yet a further embodiment. It is intended that the description includes such modifications and variations.

Carriers can be used for supporting a substrate during a sputter deposition process. During the sputter deposition process, arcing due to potential differences within a vacuum processing chamber can occur. Arcing can damage, for example, the carrier and/or the substrate. Further, arcing can affect homogeneity and/or purity of the material layer deposited on the substrate.

The embodiments of the present disclosure provide an electrically insulated or passivated carrier. As an example, the carrier can have an insulation portion and/or two or more electrically insulated segments to electrically isolate or passivate the carrier. The carrier has a reduced susceptibility to electrical potentials, and the occurrence of arcing can be reduced or even avoided. Damage to the substrate due to arcing can be prevented. Further, arcing does not affect, or interfere with, the sputter deposition process, and a homogeneity of the material layer deposited on the substrate can be improved. A contamination of the material layer due to particles created by the arcing can be reduced or even avoided.

The term “arcing” as used herein refers to an electric flashover between two points having different electric potentials. As an example, “arcing” can be understood as an electric current that flows across an open space between two points having different electrical potentials, i.e., there is a potential difference between the two points. When the potential difference exceeds a threshold value, arcing can occur. The threshold value can be referred to as “flash-over voltage” or “sparkover” voltage. The two points of different electrical potentials could be provided by the sputter deposition source (e.g., a target) and, for example, a portion of the carrier or another point provided within a vacuum processing chamber in which the carrier and the sputter deposition source are located.

The embodiments described herein can be utilized for sputter deposition on large area substrates, e.g., for lithium battery manufacturing or electrochromic windows. As an example, one or more thin film batteries can be formed on a large area substrate supported by the carrier according to the embodiments described herein. According to some embodiments, a large area substrate can be GEN 4.5, which corresponds to about 0.67 m² substrates (0.73×0.92 m), GEN 5, which corresponds to about 1.4 m² substrates (1.1 m×1.3 m), GEN 7.5, which corresponds to about 4.29 m² substrates (1.95 m×2.2 m), GEN 8.5, which corresponds to about 5.7 m² substrates (2.2 m×2.5 m), or even GEN 10, which corresponds to about 8.7 m² substrates (2.85 m×3.05 m). Even larger generations such as GEN 11 and GEN 12 and corresponding substrate areas can similarly be implemented.

According to some implementations, the carriers are configured for supporting two or more substrates. As an example, an array of substrates positioned on an inlay portion or sub-carriers (e.g., DIN A5, A4, or A3) on large carriers (e.g. with a deposition window of Gen 4.5) can be used.

The present embodiments can be used in the manufacture of, for example, thin film batteries, electrochromic windows and displays, for example, liquid crystal displays (LCD), PDPs (Plasma Display Panel), organic light-emitting diode (OLED) displays, and the like.

The term “substrate” as used herein shall particularly embrace inflexible substrates, e.g., glass plates and metal plates. However, the present disclosure is not limited thereto and the term “substrate” can also embrace flexible substrates such as a web or a foil. According to some embodiments, the substrate can be made from any material suitable for material deposition. For instance, the substrate can be made from a material selected from the group consisting of glass (for instance soda-lime glass, borosilicate glass etc.), metal, polymer, ceramic, compound materials, carbon fiber materials, mica or any other material or combination of materials which can be coated by a deposition process.

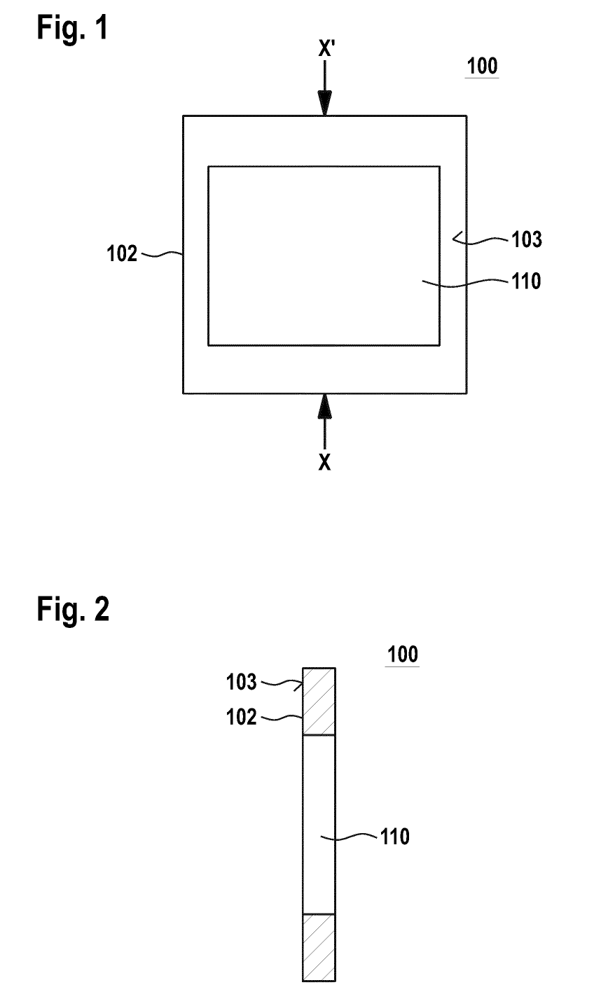

FIG. 1 illustrates a carrier 100 for supporting at least one substrate during a sputter deposition process according to embodiments described herein. FIG. 2 shows a cross-sectional side view of the carrier 100 along line X-X′.

The carrier 100 includes a carrier body 102 and an insulating portion provided at the carrier body 102. The insulating portion provides a surface 103 of an electrically insulating material. The surface 103 is configured to face one or more sputter deposition sources (not shown) during the sputter deposition process, for example, an AC sputter deposition process. The carrier 100 has a reduced susceptibility to different electrical potentials, and the occurrence of arcing can be reduced or even avoided. A damage of the substrate due to arcing can be avoided. Further, arcing does not affect, or interfere with, the sputter deposition process, and a homogeneity of the material layer deposited on the substrate can be improved. A contamination of the material layer due to particles created by the arcing can be reduced or even avoided.

An AC sputter deposition process is a sputter deposition process where the sign of the cathode voltage is varied at a predetermined rate, for example, 13.56 MHz, particularly 27.12 MHz, more particularly 40.68 MHz, or another multiple of 13.56 MHz. According to some embodiments, which can be combined with other embodiments described herein, the AC sputter deposition process can be a HF (high frequency) or RF (radio frequency) sputter deposition process. However, the present disclosure is not limited to AC sputter deposition processes and the embodiments described herein can be used in other sputter deposition processes, such as DC sputter deposition processes.

According to some embodiments, which can be combined with other embodiments described herein, the electrically insulating material can include at least one material selected from the group consisting of a non-conductive material, a ceramic material, a glass-ceramic material, and any combination thereof. In some implementations, the insulating material can be an aluminum oxide, e.g., Al₂O₃. According to some embodiments, which can be combined with other embodiments described herein, the carrier body 102 can be made of a conducting material, such as an aluminium alloy. In other examples, the carrier body 102 can be made of an electrically insulating material, e.g., of the same electrically insulating material that the insulating portion or the surface of the insulating portion is made of.

Non-conductive materials or insulators can be understood as materials which exhibit poor or even no electrical conductivity, particularly in comparison to conductive materials. Non-conductive materials or insulators have a higher resistivity than semiconductors or conductors. As an example, the conductive materials or insulators have a resistivity of at least 10¹⁰ (Ohm·m) at 20° C., specifically of at least 10¹⁴ (Ohm·m) at 20° C., and more specifically of at least 10¹⁶ (Ohm·m) at 20° C.

Glass-ceramics materials (e.g., Ceran®) can be understood as polycrystalline materials produced through controlled crystallization of a base glass. According to some embodiments described herein, the glass-ceramic material can be selected from the group including, but not limited to, Li₂O×Al₂O₃×nSiO₂-systems (LAS-systems), MgO×Al₂O₃×nSiO₂-systems (MAS-systems), ZnO×Al₂O₃×nSiO₂-systems (ZAS-systems), and any combination thereof.

In some implementations, the insulating material at least partially covers a surface of the carrier body 102. In some implementations, the insulating material can cover at least 30% of a surface or surface area of the carrier body 102. Particularly, the insulating material can cover at least 50% of a surface or surface area of the carrier body 102. More particularly, the insulating material can cover 100% of a surface or surface area of the carrier body 102. As an example, substantially the whole surface of the carrier body 102 is covered by the insulating material.

According to some embodiments, which can be combined with other embodiments described herein, the substrate can include a front surface and a back surface, wherein the front surface is a surface on which the material layer is to be deposited in the sputter deposition process. In other words, the front surface can be a surface of the substrate that is facing towards the one or more sputter deposition sources during the sputter deposition process. The front surface and the back surface can be opposing surfaces of the substrate. In other words, the back surface can be a surface of the substrate that is facing away from the one or more sputter deposition sources during the sputter deposition process.

According to some embodiments, which can be combined with other embodiments, the carrier body 102 can be a plate. The carrier body 102 can support a surface of the substrate, such as the back surface of the substrate. According to further embodiments, which can be combined with other embodiments, the carrier body 102 can include, or be, a frame having one or more frame elements. As an example, the carrier body 102 can be a rectangular-shaped frame.

In some implementations, the carrier body 102 can have an aperture opening 110. As an example, the aperture opening 110 can be defined by the one or more frame elements of the carrier body 102. The aperture opening 110 can be configured to accommodate the at least one substrate. As an example, the aperture opening 110 can be configured to accommodate one substrate, or can be configured to accommodate two or more substrates. The frame-shaped carrier body can support a surface of the substrate, e.g., along the periphery of the substrate. In some embodiments, the frame-shaped carrier body can be used to mask the substrate.

The aperture opening 110 can have a variable size. As an example, the substrate can be positioned within the aperture opening 110 and the size of the aperture opening 110 can be decreased to hold or clamp the substrate at the substrate edges. When the substrate is to be unloaded from the carrier 100, the size of the aperture opening 110 can be increased to release the substrate edges. Additionally or alternatively, the carrier can include one or more holding devices configured for holding the substrate at the carrier 100.

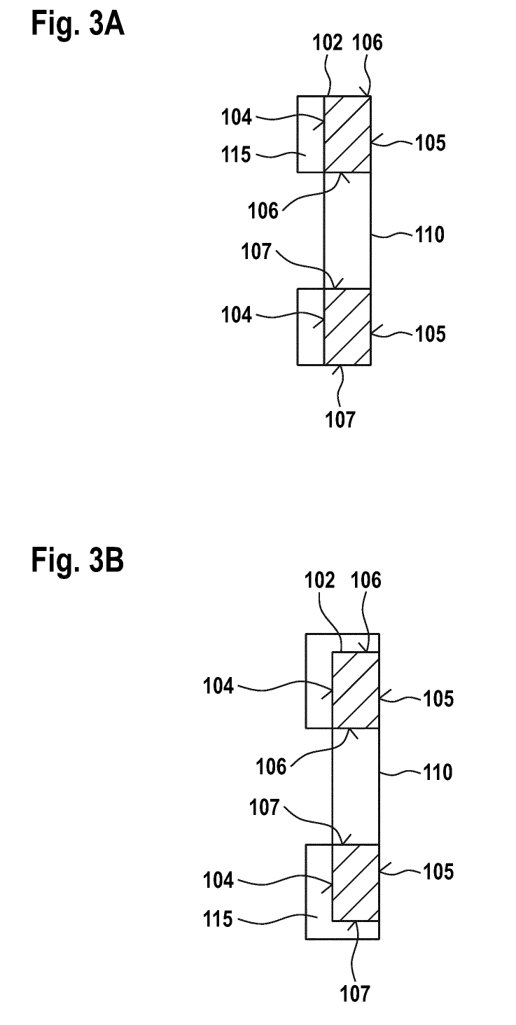

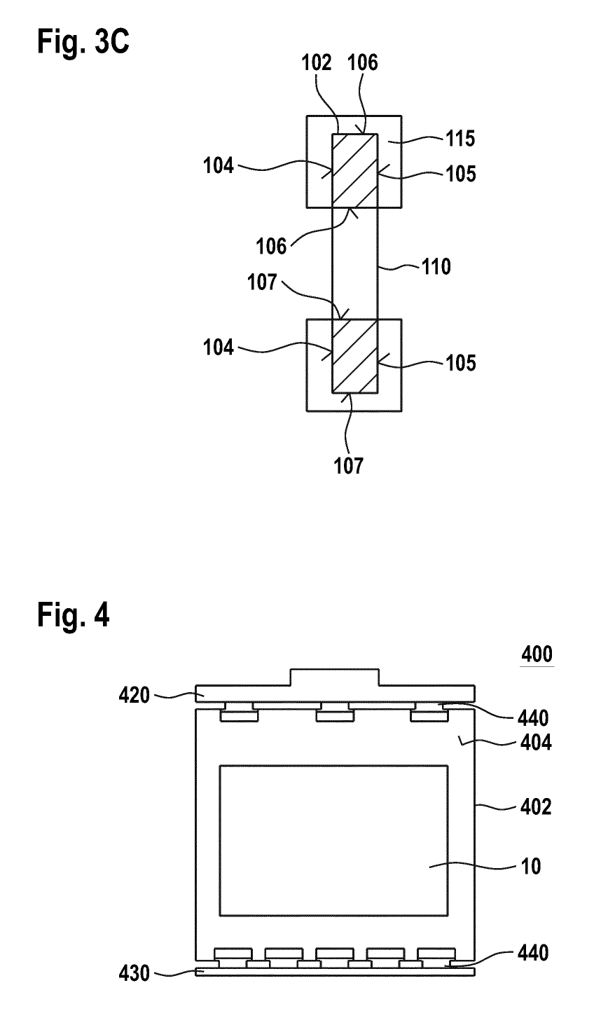

FIGS. 3A-C show cross-sectional side views of carriers according to embodiments described herein.

According to some embodiments, which can be combined with other embodiments described herein, the insulating portion is a coating 115 on the carrier body 102. In other words, the carrier body 102 is at least partially coated with the insulating material. In some implementations, the coating 115 can cover at least 30% of a surface or surface area of the carrier body 102. Particularly, the coating 115 can cover at least 50% of a surface or surface area of the carrier body 102. More particularly, the coating 115 can cover 100% of a surface or surface area of the carrier body 102. As an example, substantially the whole surface of the carrier body 102 is covered by the coating 115.

In some implementations, the carrier body 102 can include a first surface 104 (e.g., a front surface) configured to face the one or more sputter deposition sources during the sputter deposition process and a second surface 105 (e.g., a back surface). The first surface 104 and the second surface 105 can be opposing surfaces of the carrier body 102. As an example, the second surface 105 can be configured to face away from the one or more sputter deposition sources during the sputter deposition process. The at least one substrate can be provided at the first surface 104. According to some embodiments, which can be combined with other embodiments described herein, the insulating portion covers at least a portion of the front surface of the carrier body 102 and/or the back surface of the carrier body 102. As an example, the insulating portion covers substantially the complete front surface of the carrier body 102 and/or covers substantially the complete back surface of the carrier body 102.

The carrier body 102 can include side surfaces, such as at least one first side surface 106, e.g., at the top of the carrier body 102 and at least one second side surface 107, e.g., at the bottom of the carrier body 102. The at least one first side surface 106 and the at least one second side surface 107 can also be referred to as “horizontal side surfaces”. The carrier body 102 can further include at least one third side surface and at least one fourth side surface (not shown in the cross-sectional views of FIGS. 3A-C), e.g., each connecting the at least one first side surface 106 and the at least one second side surface 107. The at least one third side surface and the at least one fourth side surface can also be referred to as “vertical side surfaces”. The side surfaces can include outer side surfaces, e.g., defining an outer circumference or edge of the carrier body 102. The side surfaces can further include inner side surfaces defining the aperture opening 110.

In the example of FIG. 3A, the coating 115 can at least partially cover the first surface 104 or front side of the carrier body 102 configured to face the one or more sputter deposition sources during the sputter deposition process. In some implementations, the coating 115 covers the complete first surface 104 of the carrier body 102.

In the example of FIG. 3B, the coating 115 can at least partially or completely cover the first surface 104 or front side, and can at least partially or completely cover one or more (e.g., outer) side surfaces or corners of the carrier body 102, such as the at least one first side surface 106 and/or the at least one second side surface 107.

As exemplarily shown in FIG. 3C, the coating 115 can at least partially or completely cover the first surface 104 or front side of the carrier body 102, can at least partially or completely cover the second surface 105 or back side of the carrier body 102, and can at least partially or completely cover one or more (e.g., outer) side surfaces or corners of the carrier body 102, such as the at least one first side surface 106 and/or the at least one second side surface 107. Although not shown in the examples of FIGS. 3A-C, it is to be understood that the coating 115 can also cover at least a portion of the inner side surfaces defining the aperture opening 110.

In some implementations, the coating 115 or passivation can be provided on an area facing the one or more sputter deposition sources (e.g., the front surface of the carrier body), narrow sides of the leading edge and tailing edge of the carrier, the narrow sides at the top and the bottom of the carrier, and a backside area (e.g., the back surface) of the carrier.

According to some embodiments, which can be combined with other embodiments herein, the coating 115 can have a thickness in a range of 50 to 600 μm. Particularly, the coating 115 can have a thickness in a range of 100 to 300 μm. More particularly, the coating 115 can have a thickness in a range of 150 to 200 μm. In some embodiments, the thickness of the coating 115 can depend on a potential distribution during a sputter deposition process, for example, a potential of the one or more sputter deposition sources and/or a potential difference between the one or more sputter deposition sources and the carrier or carrier body 102. In some implementations, the thickness of the coating 115 can be selected to be higher than the voltage difference at the carrier surface generated by a RF sputter deposition process.

As used herein, the term “potential difference” can specifically refer to a potential difference between the one or more sputter deposition sources and the substrate or between the one or more sputter deposition sources and the carrier. As an example, potential values are between 50V and 600V, specifically between 100V and 400V, and more specifically between 200V and 300V. In some implementations, the thickness of the coating 115 depends on properties of the material used for the coating like at least one of dielectric strength, relative permittivity and dielectric loss angle.

According to some embodiments described herein, the coating 115 can include at least one material selected from the group consisting of: a non-conductive material, a ceramic material, a glass-ceramic material, and any combination thereof. Particularly, the coating 115 can include, or be made of, an aluminum oxide, e.g., Al₂O₃, or an silicon oxide, e.g., SiO₂.

According to some embodiments, which can be combined with other embodiments described herein, the carrier body 102 and the insulating portion can be integrally formed of the electrically insulating material. As an example, the carrier body 102 and the insulating portion can be made of a single piece of material.

FIG. 4 shows a front view of a carrier 400 according to embodiments described herein. The carrier 400 can be configured to support a substrate 10. According to some embodiments, which can be combined with other embodiments described herein, the carrier 400 includes a first transportation device 420, such as a top bar, and a second transportation device 430, such as a bottom bar. The first transportation device 420 and the second transportation device 430 can be configured for transportation of the carrier 400 along a transportation path of a processing apparatus, e.g., an inline deposition tool. The transportation path can be a linear transportation path. As an example, one or more sputter deposition sources can be arranged along the linear transportation path.

According to some embodiments, which can be combined with other embodiments herein, the carrier 400 includes one or more insulating connecting portions 440 connecting the carrier body 402 to the first transportation device 420, such as the top bar, and the second transportation device 430, such as the bottom bar. In some embodiments, the insulating connecting portions 440 can be made of a polymeric material. As an example, the insulating connecting portions 440 can be made of polyether ether ketone (PEEK). According to some implementations, the carrier body 402 has the insulating portion providing the surface 404 of the electrically insulating material to electrically insulate the carrier 400 or at least the carrier body 402, e.g., during the sputter deposition process.

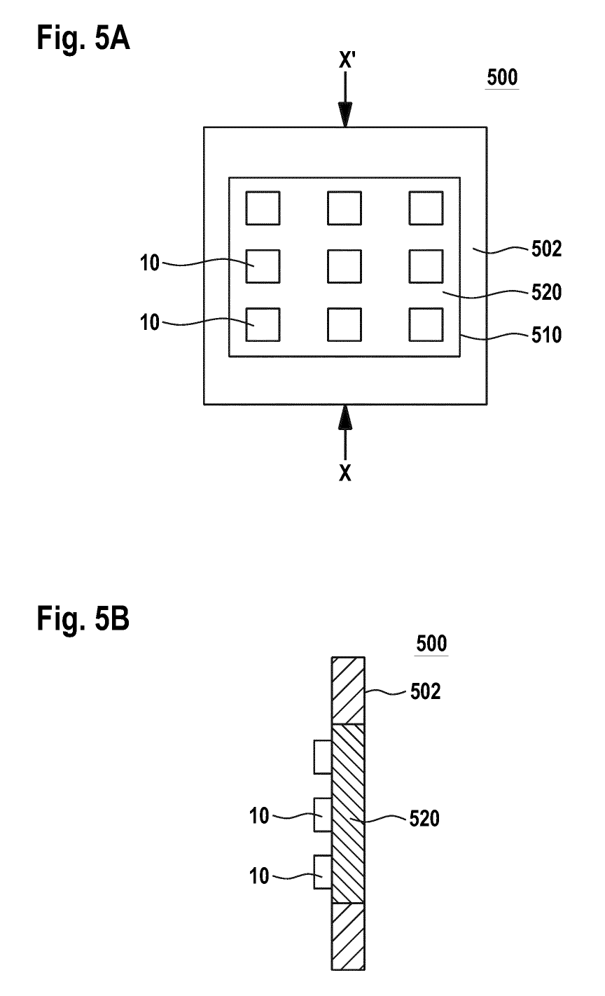

FIG. 5A shows a front view of a carrier 500 configured for supporting two or more substrates 10 during a sputter deposition process according to embodiments described herein. FIG. 5B shows a cross-sectional view of the carrier 500 of FIG. 5A.

According to some embodiments, which can be combined with other embodiments described herein, the carrier 500 includes the carrier body 502 having an aperture opening 510 configured to accommodate an inlay portion 520. The inlay portion 520 can be configured to support two or more substrates 10. According to some embodiments, which can be combined with other embodiments described herein, the inlay portion 520 can be configured to support five or more substrates, particularly ten or more substrates, and more particularly 20 or more substrates.

According to some embodiments, the inlay portion 520 can be a plate. In some implementations, the inlay portion 520 can be configured to be detachable from the carrier 500 or carrier body 502. As an example, the inlay portion 520 can be configured to be attached to, and detached from, the aperture opening 510. The inlay portion 520 can have a size corresponding to the size of the aperture opening 510. As an example, the inlay portion 520 can be held or fixed in the aperture opening 510.

In some implementations, the carrier 500 can include the insulating portion provided at the carrier body 502. The insulating portion and/or the carrier body 502 and the inlay portion 520 can be made of, or coated with, the electrically insulating material. In other words, the insulating portion and/or the carrier body 502 and the inlay portion 520 can be made of the same material or can be coated with the same material. According to further embodiments, the carrier body 502 and the inlay portion 520 can be made of different materials. According to some embodiments, which can be combined with other embodiments described herein, a surface of the inlay portion 520 is at least partially covered with the electrically insulating material. As an example, a surface (e.g., a front surface) of the inlay portion 520 configured to face the one or more sputter deposition sources during the sputter deposition process and/or configured to support the at least one substrate can at least partially, and specifically completely, be covered or coated with the electrically insulating material. Additionally or alternatively, another surface (e.g., a back surface) of the inlay portion 520 configured to face away from the one or more sputter deposition sources during the sputter deposition process can at least partially, and specifically completely, be covered or coated with the electrically insulating material.

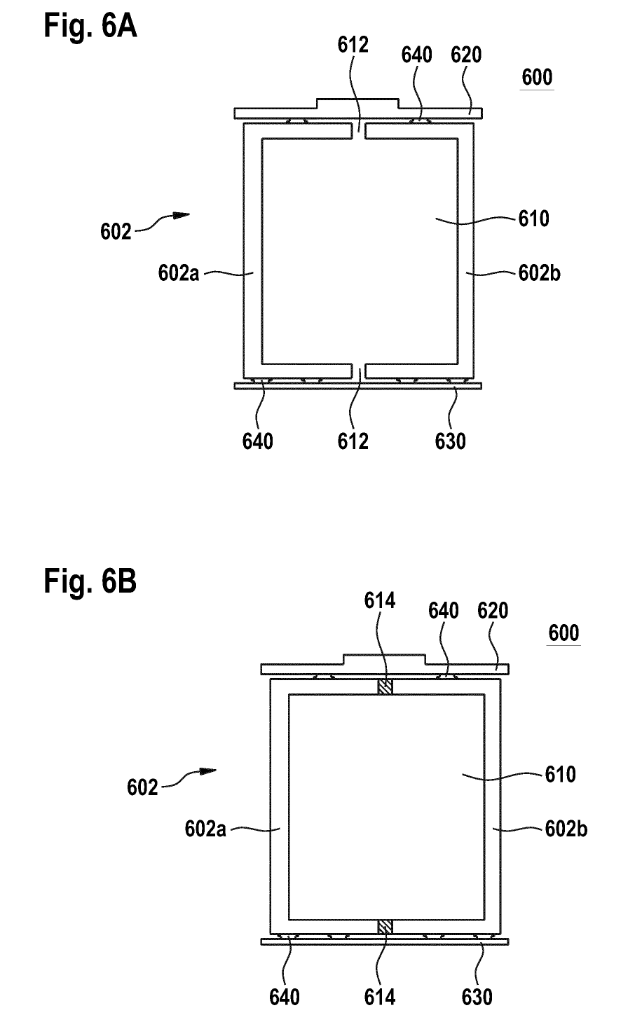

FIG. 6A shows a front view of a carrier 600 for supporting at least one substrate during a sputter deposition process according to embodiments described herein. The carrier 600 includes a carrier body 602 having two or more segments, such as a first segment 602a and a second segment 602b. As an example, the carrier body 602 can be vertically divided to form the two or more segments. The two or more segments are configured for supporting the at least one substrate.

The two or more segments, such as the first segment 602a and the second segment 602b, are electrically insulated from each other. The two or more segments can reduce or even avoid situations where the carrier 600 is exposed to two different potentials, e.g., two different RF potentials or plasma potentials during the sputter deposition process. The two different potentials could, for example, originate from two different sputter deposition sources when the carrier 600 passes two sputter deposition sources arranged side by side in one deposition chamber. For instance, the first segment 602a can be configured to face a first sputter deposition source of the one or more sputter deposition sources and the second segment 602b can be configured to face a second sputter deposition source of the one or more sputter deposition sources.

The two or more segments can be plates or frames. In the examples illustrated in FIGS. 6A and 6B, the two or more segments are C-shaped with the open portions of the C-shapes being oriented towards each other. As an example, the first segment 602a can form a “C”, and the second segment 602b can form an inverted or mirrored “C”. The carrier body 602 can have an aperture opening 610, for example, provided or defined by the two or more segments. The aperture opening 610 can be configured to accommodate an inlay portion as described with respect to FIGS. 5A and 5B.

According to some embodiments, which can be combined with other embodiments described herein, the carrier 600 includes a first transportation device 620, such as a top bar, and a second transportation device 630, such as a bottom bar. The first transportation device 620 and the second transportation device 630 can be configured for transportation of the carrier 600 along a transportation path of a processing apparatus, e.g., an inline deposition tool. The transportation path can be a linear transportation path. As an example, one or more sputter deposition sources can be arranged along the linear transportation path.

According to some embodiments, which can be combined with other embodiments herein, the carrier 600 includes one or more insulating connecting portions 640 connecting the carrier body 602 to the first transportation device 620, such as the top bar, and the second transportation device 630, such as the bottom bar. In some embodiments, the insulating connecting portions 440 can be made of a polymeric material. As an example, the insulating connecting portions 440 can be made of polyether ether ketone (PEEK). In some implementations, the two or more segments can have a common first transportation device 620 (top bar) and a common second transportation device 630 (bottom bar), which are electrically insulated to each segment of the two or more segments.

According to some embodiments, the carrier body 602 can include a gap 612 between the first segment 602a and the second segment 602b. The gap 612 can be configured to electrically isolate the first segment 602a and the second segment 602b from each other. The term “gap” as used herein can refer to an area or separation area between the two or more segments where the two or more segments do not contact each other. As an example, the first segment 602a and the second segment 602b can be distanced or spaced apart from each other. According to some embodiments, the gap 612 can be an empty area, as shown in FIG. 6A. According to further embodiments, the gap 612 can be partially or completely filled with an insulator 614, as shown in FIG. 6B. The insulator 614 can include, or be made of, a polymeric material, such as polyether ether ketone (PEEK), or a ceramic.

According to some embodiments of the present disclosure, the sputter deposition sources can be rotatable sputter deposition sources or rotatable cathodes. The sputter deposition sources can be rotatable around a rotational axis. As an example, the rotational axis can be a vertical rotational axis. According to some embodiments, which can be combined with other embodiments described herein, the gap 612 can be configured to extend in a direction substantially parallel to the rotational axis of the one or more sputter deposition sources. The term “substantially parallel” relates to a substantially parallel orientation, e.g., of the rotational axis and the gap, wherein a deviation of a few degrees, e.g. up to 10° or even up to 15°, from an exact parallel orientation is still considered as “substantially parallel”. However, the present disclosure is not limited to rotatable sputter deposition sources or rotatable cathodes. According to some embodiments, which can be combined with other embodiments described herein, the sputter deposition sources can be planar sputter deposition sources or planar cathodes. The gap 612 could then extend substantially parallel to an extended surface of the planar sputter deposition sources.

As an example, the gap can, for example, vertically divide the carrier body 602 into the two or more segments. The gap that divides the carrier body 602 substantially parallel to the rotational axis of the sputter deposition sources can reduce or even avoid situations where the carrier 600 is exposed to two different potentials, e.g., two different RF potentials or plasma potentials originating from two different sputter deposition sources positioned side by side in one deposition chamber.

According to some embodiments, which can be combined with other embodiments described herein, the carrier 600 can further include an insulating portion provided at the carrier body 602, wherein the insulating portion provides a surface of an electrically insulating material. The surface of the electrically insulating material can be configured to face one or more sputter deposition sources (not shown) during the sputter deposition process. According to some embodiments described herein, the insulating portion of the carrier 600 can be configured according to the embodiments described with reference to FIGS. 1 to 5. As an example, the insulating portion could be provided as a coating on the carrier body 602.

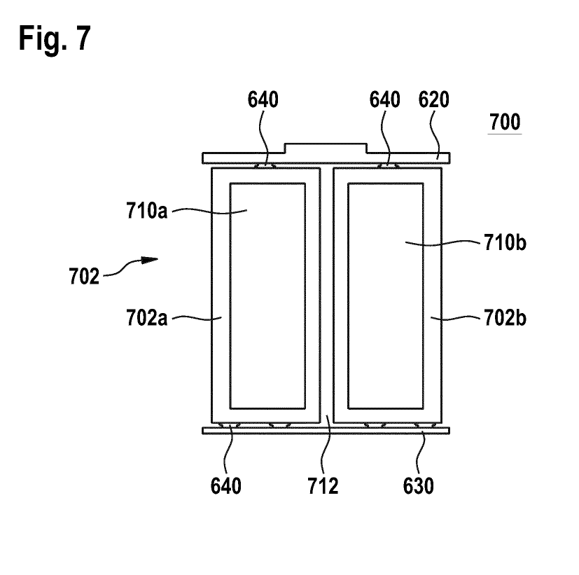

FIG. 7 shows a carrier 700 for supporting at least one substrate during a sputter deposition process according to further embodiments described herein. The carrier 700 includes a carrier body 702 having a first segment 702a and a second segment 702b separated by a gap 712. The gap 712 can be configured as described with reference to FIGS. 6A and 6B, e.g., as an empty gap or with an insulator provided therein.

The two or more segments can be plates or frames. In the example illustrated in FIG. 7, the two or more segments are O-shaped (e.g., ring-shaped) frames arranged adjacent to each other. As an example, the two or more segments can be rectangular frames. The first segment 702a can include a first aperture opening 710a configured to accommodate a first substrate or a first inlay portion. Likewise, the second segment 702b can include a second aperture opening 710b configured to accommodate a second substrate or a second inlay portion. The first inlay portion and the second inlay portion can be configured as described with respect to FIGS. 5A and 5B.

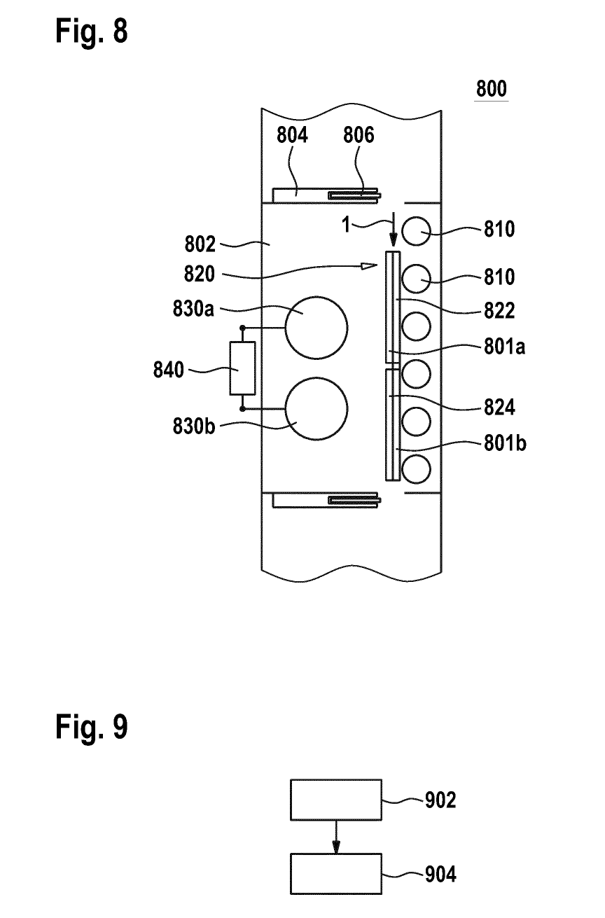

FIG. 8 shows a schematic view of an apparatus 800 for sputter deposition on a substrate.

According to some embodiments described herein, the apparatus 800 includes a vacuum chamber 802 (also referred to as “deposition chamber” or “vacuum processing chamber”), one or more sputter deposition sources, such as a first sputter deposition source 830a and a second sputter deposition source 830b in the vacuum chamber 802, and a carrier 820 for supporting at least one substrate, such as a first substrate 801a and a second substrate 801b, during a sputter deposition. Although the carrier 820 is illustrated as a segmented carrier, the carrier 820 could be configured according to any one of the embodiments described herein. The first sputter deposition source 830a and the second sputter deposition source 830b can, for example, be rotatable cathodes having targets of the material to be deposited on the substrate(s).

As indicated in FIG. 8, further chambers can be provided adjacent to the vacuum chamber 802. The vacuum chamber 802 can be separated from adjacent chambers by a valve having a valve housing 804 and a valve unit 806. After the carrier 805 with the at least one substrate thereon is, as indicated by arrow 1, inserted into the vacuum chamber 802, the valve unit 806 can be closed. The atmosphere in the vacuum chambers 802 can be individually controlled by generating a technical vacuum, for example with vacuum pumps connected to the vacuum chamber, and/or by inserting process gases in a deposition region in the vacuum chamber 802.

According to some embodiments, process gases can include inert gases such as argon and/or reactive gases such as oxygen, nitrogen, hydrogen and ammonia (NH3), Ozone (O3), activated gases or the like. Within the vacuum chamber 802, rollers 810 can be provided in order to transport the carrier 820, having the first substrate 801a and the second substrate 801b thereon, into and out of the vacuum chamber 802.

According to some embodiments, which can be combined with embodiments described herein, the carrier 820 can include a carrier body having two or more segments, such as a first segment 822 and a second segment 824, configured for supporting a first substrate 801a and a second substrate 801b during the sputter deposition process. As shown in FIG. 8, the first segment 822 can support the first substrate 801a and the second segment 824 can support the second substrate 801b.

According to some embodiments described herein, the first segment 822 can be configured to face the first sputter deposition source 830a and the second segment 824 can be configured to face the second sputter deposition source 830b, for example, in a static deposition process. The carrier 820 is vertically divided into the two or more segments. The gap that divides the carrier body 602 can be substantially parallel to the rotational axis of the sputter deposition sources to reduce or even avoid situations where the carrier 600 is exposed to two different potentials, e.g., two different RF potentials or plasma potentials originating from two different sputter deposition sources positioned side by side in one deposition chamber.

The sputter deposition process can be an RF frequency (RF) sputter deposition process. As an example, the RF sputter deposition process can be used when the material to be deposited on the substrate is a dielectric material. Frequencies used for RF sputter processes can be about 13.56 MHZ or higher.

According to some embodiments described herein, the apparatus 800 can have an AC power supply 840 connected to the one or more sputter deposition sources. As an example, the first sputter deposition source 830a and the second sputter deposition source 830b can be connected to the AC power supply 840 such that the first sputter deposition source 830a and the second sputter deposition source 830b can be biased in an alternating manner. The one or more sputter deposition sources can be connected to the same AC power supply. In other embodiments, each sputter deposition source can have its own AC power supply.

According to embodiments described herein, the sputter deposition process can be conducted as magnetron sputtering. As used herein, “magnetron sputtering” refers to sputtering performed using a magnet assembly, e.g., a unit capable of generating a magnetic field. Such a magnet assembly can consist of a permanent magnet. This permanent magnet can be arranged within a rotatable target or coupled to a planar target in a manner such that the free electrons are trapped within the generated magnetic field generated below the rotatable target surface. Such a magnet assembly can also be arranged coupled to a planar cathode. Magnetron sputtering can be realized by a double magnetron cathode, e.g. the first sputter deposition source 830a and the second sputter deposition source 830b, such as, but not limited to, a TwinMag™ cathode assembly.

According to some embodiments, which can be combined with other embodiments described herein, the apparatus 800 can be configured to deposit lithium or a lithium alloy on the at least one substrate. In some implementations, the apparatus 800 can be configured to deposit at least one of a metal oxide, such as Al₂O₃ or SiO₂, and a target material. The target material can include one or more element(s) selected from the group consisting of lithium, tantalum, molybdenum, niobium, titanium, manganese, nickel, cobalt, indium, gallium, zinc, tin, silver, copper, and any combination thereof. In particular, the apparatus can be configured to deposit lithium phosphorus oxynitride (LiPON) on the at least one substrate. LiPON is an amorphous glassy material used as an electrolyte material in thin film batteries. Layers of LiPON can be deposited over a cathode material of a thin film battery by RF magnetron sputtering forming a solid electrolyte.

The carriers and the apparatuses utilizing the carriers described herein can be used for vertical substrate processing. According to some implementations, the carrier of the present disclosure is configured for holding the at least one substrate in a substantially vertical orientation. The term “vertical substrate processing” is understood to distinguish over “horizontal substrate processing”. For instance, vertical substrate processing relates to a substantially vertical orientation of the carrier and the substrate during substrate processing, wherein a deviation of a few degrees, e.g. up to 10° or even up to 15°, from an exact vertical orientation is still considered as vertical substrate processing. The vertical direction can be substantially parallel to the force of gravity. As an example, the apparatus 800 for sputter deposition on at least one substrate can be configured for sputter deposition on a vertically oriented substrate.

According to some embodiments, the carrier and the substrate are static or dynamic during sputtering of the deposition material. According to some embodiments described herein, a dynamic sputter deposition process can be provided, e.g., for thin film battery manufacturing. The embodiments of the present disclosure can be particularly beneficial for such dynamic sputter deposition processes, since electrically conducting materials moving through a RF plasma can cause arcing due to different electrical potentials. The electrical insulation provided by the embodiments of the present disclosure can reduce or even avoid the occurrence of arcing, in particular when the carrier moves through the vacuum processing chamber.

FIG. 9 shows a flow chart illustrating a method for sputter deposition on at least one substrate according to embodiments described herein.

The method includes, in block 902, a positioning of the at least one substrate on a carrier according to the embodiments described herein. As an example, the carrier includes a carrier body and an insulating portion provided at the carrier body. The insulating portion provides a surface of an electrically insulating material. The carrier body can, additionally or alternatively, have two or more segments, wherein the two or more segments are configured for supporting the at least one substrate, and wherein the two or more segments are electrically insulated from each other. The method further includes, in block 904, a depositing of a layer of a material on the at least one substrate using an AC sputter deposition process.

According to embodiments described herein, the method for sputter deposition on at least one substrate can be conducted by means of computer programs, software, computer software products and the interrelated controllers, which can have a CPU, a memory, a user interface, and input and output means being in communication with the corresponding components of the apparatus for sputter deposition on at least one substrate.

The embodiments of the present disclosure provide an electrically insulated or passivated carrier. As an example, the carrier can have an insulation portion and/or two or more electrically insulated segments to electrically isolate or passivate the carrier. The carrier has a reduced susceptibility to electrical potentials, and the occurrence of arcing can be reduced or even avoided. Damage to the substrate due to arcing can be avoided. Further, arcing does not affect, or interfere with, the sputter deposition process, and a homogeneity of the material layer deposited on the substrate can be improved. A contamination of the sputtered material layer due to particles created by the arcing can be reduced or even avoided.

While the foregoing is directed to embodiments of the present disclosure, other and further embodiments can be devised without departing from the basic scope thereof, and the scope thereof is determined by the claims that follow.

1. A carrier for supporting at least one substrate during a sputter deposition process, comprising:
a carrier body; and
an insulating portion provided at the carrier body, wherein the insulating portion provides a surface of an electrically insulating material, wherein the surface is configured to face one or more sputter deposition sources during the sputter deposition process.

2. A carrier for supporting at least one substrate during a sputter deposition process, comprising:
a carrier body comprising two or more segments, wherein the two or more segments are configured for supporting the at least one substrate, and wherein the two or more segments are electrically insulated from each other.

3. The carrier of claim 2, comprising an insulating portion provided at the carrier body, wherein the insulating portion provides a surface of an electrically insulating material, and wherein the surface is configured to face one or more sputter deposition sources during the sputter deposition process.

4. The carrier of claim 1, wherein the insulating portion is a coating on the carrier body.

5. The carrier of claim 4, wherein the coating has a thickness in a range of 50 to 600 μm.

6. The carrier of claim 1, wherein the insulating portion covers at least 30% of a surface of the carrier body.

7. The carrier of claim 1, wherein the insulating portion covers at least a portion of a front surface of the carrier body and a back surface of the carrier body.

8. The carrier of claim 2, wherein the carrier body comprises a gap between the two or more segments, wherein the gap is configured to electrically isolate the two or more segments from each other.

9. The carrier of claim 8, wherein the gap is configured to extend in a direction parallel to a rotational axis of the one or more sputter deposition sources.

10. The carrier of claim 1, wherein the electrically insulating material includes at least one material selected from the group consisting of: a non-conductive material, a ceramic material, a glass-ceramic material, and any combinations thereof.

11. The carrier of claim 1, wherein the carrier body comprises an aperture opening configured to accommodate an inlay portion, wherein the inlay portion is configured to support the at least one substrate.

12. The carrier of claim 11, wherein a surface of the inlay portion is at least partially covered with the electrically insulating material.

13. An apparatus for sputter deposition on at least one substrate, the apparatus comprising:
a vacuum chamber;
one or more sputter deposition sources in the vacuum chamber
a carrier for supporting the at least one substrate during a sputter deposition process, the carrier comprising:
a carrier body; and
an insulating portion provided at the carrier body, wherein the insulating portion provides a surface of an electrically insulating material, wherein the surface is configured to face one or more sputter deposition sources during the sputter deposition process.

14. The apparatus of claim 13, wherein the carrier comprises the two or more segments including a first segment and a second segment, wherein the first segment is configured to face a first sputter deposition source of the one or more sputter deposition sources and the second segment is configured to face a second sputter deposition source of the one or more sputter deposition sources.

15. A method for sputter deposition on at least one substrate comprising:
positioning the at least one substrate on a carrier, the carrier comprising a carrier body;
an insulating portion provided at the carrier body, wherein the insulating portion provides a surface of an electrically insulating material, wherein the surface is configured to face one or more sputter deposition sources during the sputter deposition process; and
depositing a layer of a material on the at least one substrate using an AC sputter deposition process.

16. The carrier of claim 2, wherein the insulating portion is a coating on the carrier body.

17. The carrier of claim 3, wherein the insulating portion is a coating on the carrier body.

18. The carrier of claim 2, wherein the insulating portion covers at least a portion of a front surface of the carrier body and a back surface of the carrier body.

19. The carrier of claim 2, wherein the carrier body comprises an aperture opening configured to accommodate an inlay portion, wherein the inlay portion is configured to support the at least one substrate.

20. The carrier of claim 3, wherein the carrier body comprises an aperture opening configured to accommodate an inlay portion, wherein the inlay portion is configured to support the at least one substrate.
